(19) United States
(12) Patent Application Publication
(10) Pub. No.: US 2014/0257727 A1
(43) Pub. Date: Sep. 11, 2014

(54) Method for Angle-Preserving Phase Embeddings

(71) Applicant: MITSUBISHI ELECTRIC RESEARCH LABORATORIES, INC., Cambridge, MA (US)

(72) Inventor: Petros T. Boufounos, Boston, MA (US)

(73) Assignee: MITSUBISHI ELECTRIC RESEARCH LABORATORIES, INC., Cambridge, MA (US)

(21) Appl. No.: 13/792,356

(22) Filed: Mar. 11, 2013

(51) Int. Cl. G01R 13/02; G06F 17/30

(52) U.S. Cl. CPC G01R 13/029; G06F 17/30424
USPC 702/66; 707/769

(57) ABSTRACT

One or more signal are embedded by producing complex-valued measurements of the signal by measuring the signal using a complex measurement matrix. Then, only a phase of the complex-valued measurements are retinas, such that angles of the signal are preserved. Subsequently, the phases, which can be quantized and stored in a database, can be searched to locate similar signals based only on their phase angles.

### RELATED APPLICATION

This Application is related to U.S. Patent Appliction MERL-2638 co-filed herewith, and incorporated herein by reference. Both Applications relate to representations that preserve the angles between signals by measuring the angles with a complex linear matrix and retaining only the phase of the measurements.

### FIELD OF THE INVENTION

This invention relates generally to signal processing, and more particularly to randomized embeddings of angles between signals, which are captured by the phase of complex linear measurements.

### BACKGROUND OF THE INVENTION

Randomized embeddings have an increasingly important role in signal processing. The embeddings map signals to a space that is computationally advantageous, while preserving some aspect of the geometry of the signals. Thus, computationally efficient operations on the embedded signals can directly map to operations in the original space.

For example, the well known Johnson-Lindestrauss (J-L) embeddings reduce dimensionality while preserving the l₂ distance. The embedings are functions f:S→ [symbol] ^{K} that map a set of signals S⊂ [symbol] ^{N} to a K-dimensional vector space, such that the images of any two signals x and y in S satisfy:

$$( 1 - ɛ ) {‖ x - y ‖}_{2}^{2} \leq {‖ f ( x ) - f ( y ) ‖}_{2}^{2} \leq ( 1 + ɛ ) {‖ x - y ‖}_{2}^{2} .$$

When these embeddings are uniformly quantized to B bits per dimension, the embedding guarantee becomes

(1−ε)∥x−y∥₂−2^{-B+1}S≦∥f(x)−f(y)∥₂≦(1+ε)∥x−y∥₂+2^{-B+1}S,

where S is a quantizer saturation level, which is set to ensure negligible saturation, see U.S. application Ser. No. 13/525,222.

Quantized embeddings are used in many applications, such as augmented reality, that require efficient transmission for pattern matching, see e.g., Applicant's U.S. application Ser. No. 13/456,218, “Method for Synthesizing a Virtual Image from a Reduced Resolution Depth Image.” However, in many applications, the l₂ distance is not an appropriate metric.

### SUMMARY OF THE INVENTION

The phase of randomized complex-valued projections of signals preserves information about the angle, i.e., the correlation, between signals. This information, can be exploited to design quantized angle-preserving embeddings, which represent such correlations using a finite bit-rate. These embeddings relate to binary embeddings, 1-bit compressive sensing, and reduce the embedding uncertainty given the bit-rate.

### BRIEF DESCRIPTION OF THE DRAWINGS

FIG. 1 is a block diagram of a system and method for embedding phases of signals accoridng to emebodiments of the invention; and

FIG. 2 is a block diagram of a system and method for estimating angles of signals from their embedings according to embodiments of the invention; and

FIGS. 3, 4, and 5 are graphs comparing embedding performance as a function of embedding distances and signal distances for pairs of signals with different angles at different rates per measurement.

### DETAILED DESCRIPTION OF THE DREFERRED AMBODIMENS

The embodiments of the invention, provide a method for embedding phases of signals that preserve angles of the signals, i.e., correlations. We use the normalized angle between two signals x and x′ defined as

$${d}_{∠} = \frac{1}{π} arc cos \frac{〈 x , {x}^{′} 〉}{‖ x ‖ ‖ {x}^{′} ‖} . \qquad ( 1 )$$

Often, especially when signals are normalized, the angle between signals is more informative for comparisons than the distance. Thus, angle-preserving embeddings can produce more efficient encodings.

Angle embeddings have been used in the prior art in the context of 1-bit compressive sensing. A binary ε-stable embedding encodes signals using a random projection followed by a 1-bit scalar quantizer that only encodes the sign of each coefficient:

q=sign(Ax). (2)

There, a normalized angle between two signals x and x′ embedded in q and q′, respectively, was preserved in the normalized Hamming distance between their embeddings, as follows:

|d_{H}(q,q′)−d∠(x,x′)|≦ε, (3)

where d_{H}(x,x′)=(Σᵢxᵢ⊕x′ᵢ/K denotes the normalized Hamming distance between the signal embeddings.

The embodiments consider phase embeddings that are obtained by first projecting, the signal to a complex-valued space and only preserving and quantizing the phase of the projection coefficients:

y=Q(∠(A_{c}x)), (4)

where A_{c}∈^{K×N} is a complex-valued matrix. In the preferred embodiment it consists of i.i.d. elements drawn from a conventional complex normal distribution. In equation (4), the the quantizer Q(·) is optional.

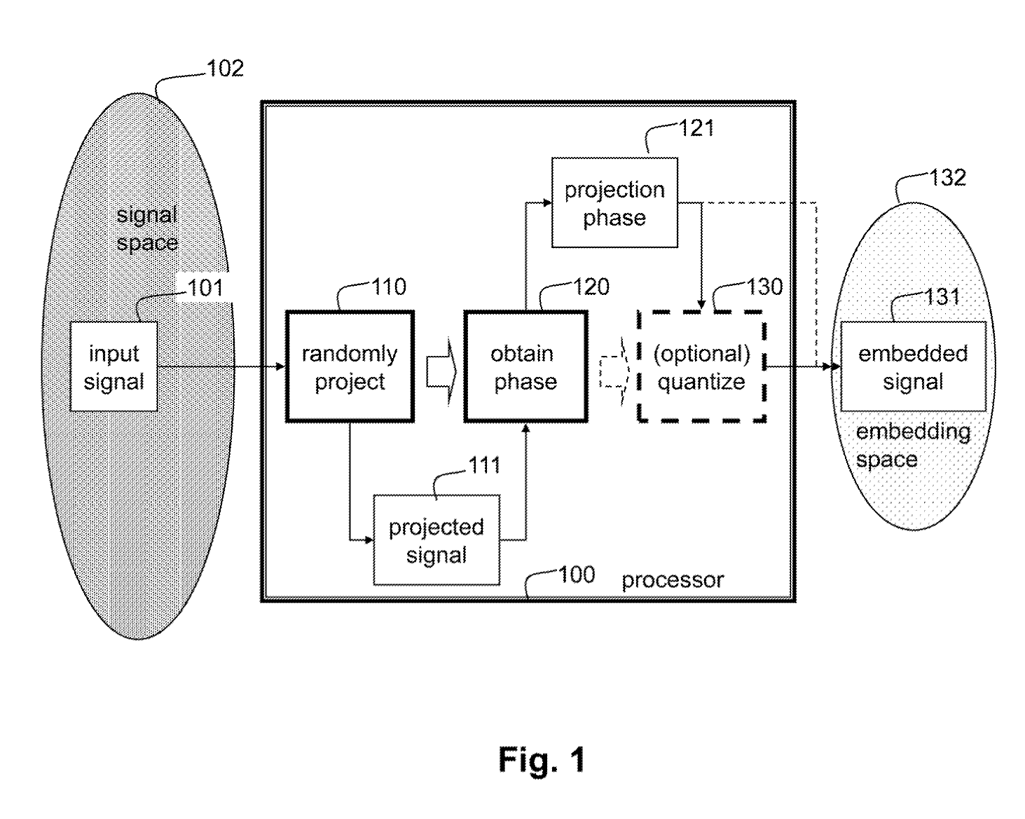

The described embedding is shown in FIG. 1. The embedding can be performed in a processor 100. The input signal x 101, which belongs in a signal space 102, is first randomly projected 110 using the matrix A_{c} to obtain the projected signal A_{c}x 111. The phase of the projection 121 is obtained from the projected signal 120. Optionally the phase may be quantized 130. The phase or the quantized phase constitutes the embedded signal 131, which lies in an embedding space 132.

This transformation preserves the angles between signals by first stablishing that, given a pair of signals x and x′, the expected value of the phase difference of their projection coefficients is proportional to their angles.

Defining Δφᵢ=∠(e^{i(y}^{ᵢ}^{-y}^{ᵢ}^{·)}), where ∠(·) measures the principal phase, the expected value equals E{|Δφᵢ|}=πd_{S}(x,x′). Using Hoeffding's inequality we can show that without the quantizer Q(·)

$$\vert {\sum }_{i}^{ } \vert \frac{Δ {φ}_{i}}{K π} \vert - {d}_{s} ( x , {x}^{′} ) \vert \leq ɛ \qquad ( 5 )$$

with probability greater than 1-2e² log L−2ε^{²}^{K}. Thus, similar to J-L embeddings, K=O(log L) dimensions are sufficient to embed a set of L points.

Using known methods, the argument can be extended to infinite signal sets such as sparse signals. When the embedding is quantized to B bits per dimension, the guarantee becomes

$$ɛ - {2}^{- B + 1} π \leq \vert {\sum }_{i}^{ } \vert \frac{Δ {φ}_{i}}{K π} \vert - {d}_{s} ( x , {x}^{′} ) \vert \leq ɛ + {2}^{- B + 1} π . \qquad ( 6 )$$

Since these embeddings preserve angles, i.e., correlations, the angle of two signals can be approximately computed simply by first embedding the signals according to equation (4) and then computing the angle in the embedding domain. The angle can be estimated using only their embeddings. The angle estimate is

$$\overline{{d}_{s} ( x , {x}^{′} )} \approx {\sum }_{i}^{ } \vert \frac{Δ {φ}_{i}}{K π} \vert . \qquad ( 7 )$$

Using this estimate it is possible to compare signals and determine how similar the signals are with respect to their correlations.

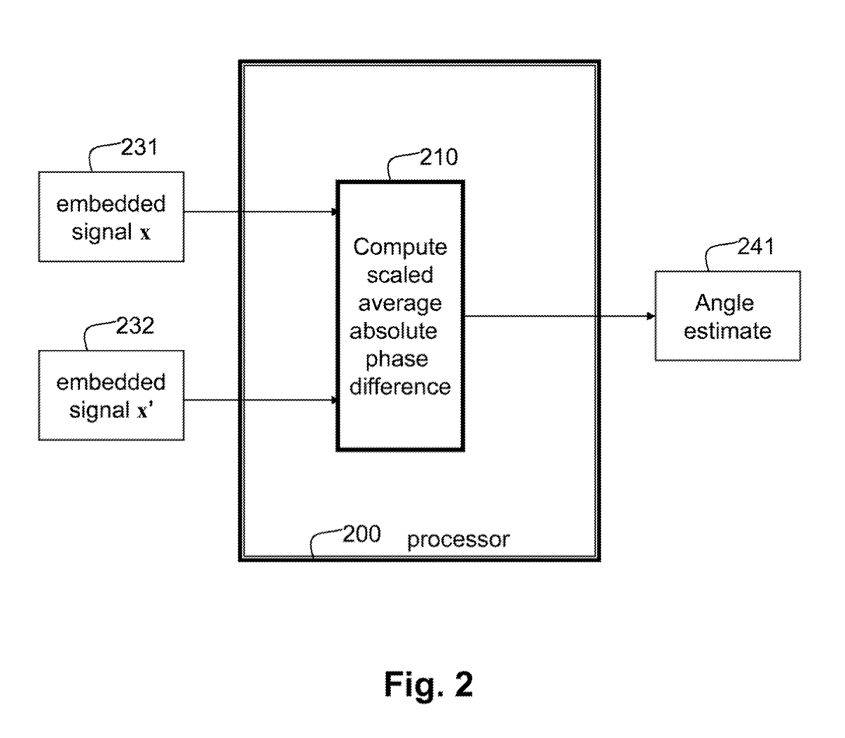

FIG. 2 shows the steps of angle estimation. Two embedded signals x 231 and x′ 232 are processed in a processor 200. The scaled absolute phase difference is computed 210 according to equation (7) to produce the angle estimate 241.

In many applications a signal is often used as a querry from a client to a database (memory) at a server, aiming to retrieve similar signals from that database, or metadata related to the similar signals. The similarity metric can be the l₂ distance; for example see see U.S. application Ser. No. 13/525,222, and 13/733,517. Very often, however, the angle, i.e., the normalized correlation, is the appropriate metric. In this case using the embedding instead of the actual signals can reduce the computation time of the search since the dimensionality of the embedding can be much lower than the dimensionality of the signals.

Often it might be necessary to transmit the signal before the signal is compared to other signals or data stored in a database. For example, in augmented reality applications and in image-based search application, a signal, or a vector of features extracted from the signal, is transmitted to a central server which performs the search. Transmitting a quantized embedding of the signal or the features, computed using equation (4), uses KB total bits. This is significantly smaller than transmitting the entire signal or its features. Thus, transmitting the embedding can significantly reduce the communication bandwidth necessary.

These embeddings are a generalization of 1-bit embeddings because the phase of complex signals generalizes the sign of real-valued signals. Thus, similar to 1-bit embeddings, phase embeddings eliminate magnitude information from the signals but preserve sufficient information to allow angle computations.

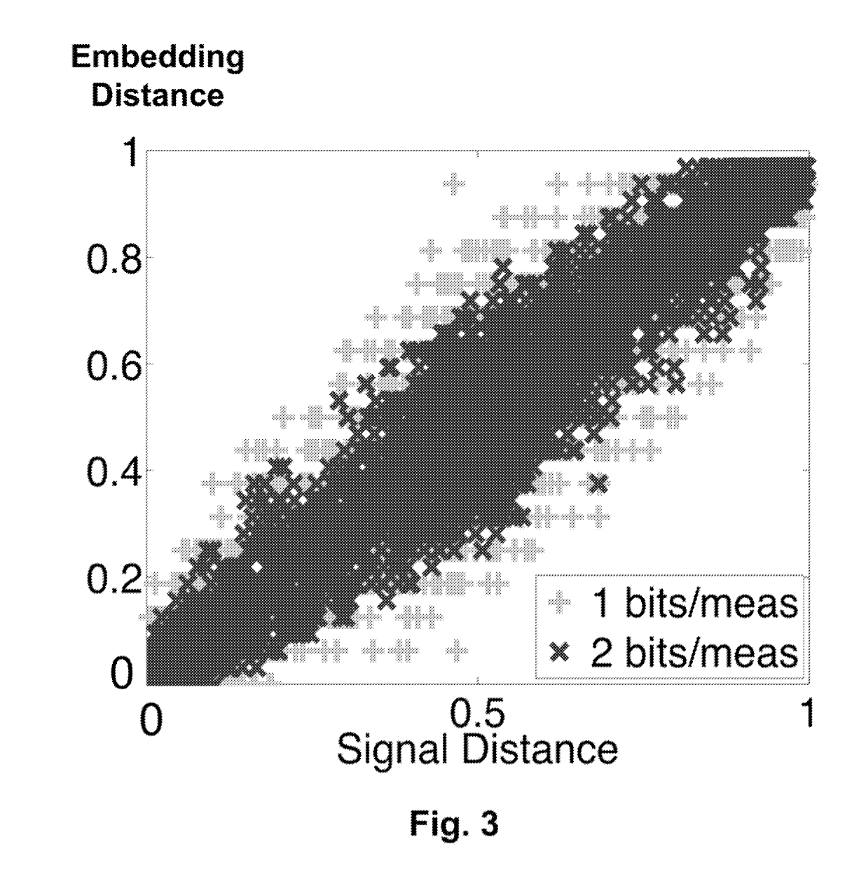

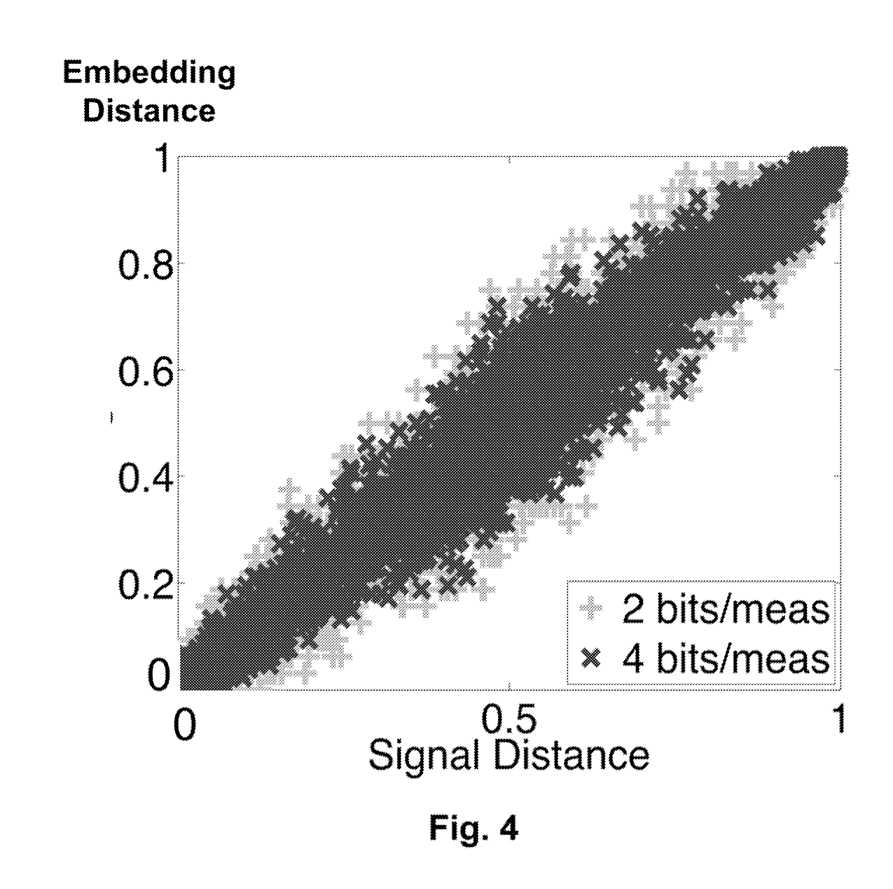

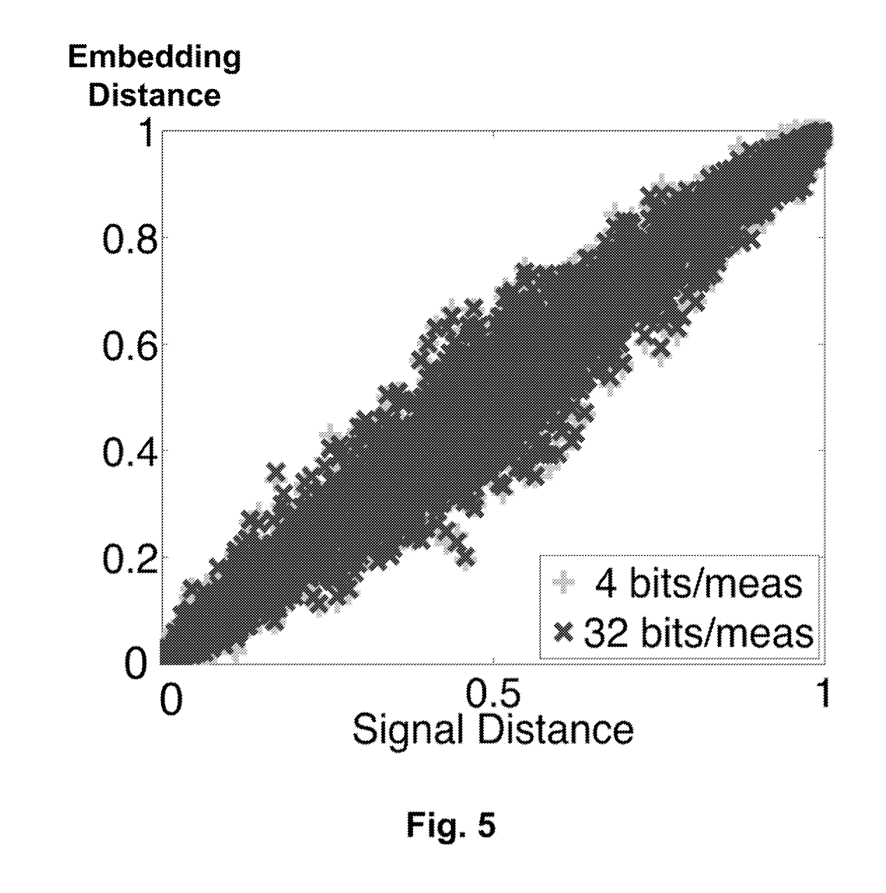

FIGS. 3, 4 and 5 compares the embedding performance, plotting simulation results on pairs of signals with different angles, as embedded with different rate per measurement. Quantized angle embeddings capture the true angle between signals with some uncertainty depending to quantization rate. FIG. 3 shows 1 vs. 2 bits/measurement, FIG. 4 shows 1 vs. 4 bits/measurement, FIG. 5 shows 4 vs. 32 bits/measurement. As expected, finer quantization per measurement improves the embedding accuracy. However, the benefits beyond 4 bits per measurement are small. Furthermore, as the rate per measurement increases, the total rate also increases, which should be taken into account in system design.

It should be understood that one can formulate convex programs for sparse reconstruction using only the phase of complex projections of a signal, i.e., phase-only compressive sensing.

Although the invention has been described by way of examples of preferred embodiments, it is to be understood that various other adaptations and modifications can be made Within the spirit and scope of the invention. Therefore, it is the object of the appended claims to cover all such variations and modifications as come within the true spirit and scope of the invention.

I claim:

1. A method for embedding a signal, comprising the steps of:
producing complex-valued measurements of the signal by measuring the signal using a complex measurement matrix; and
retaining only a phase of the complex-valued measurements such that angles of the signal are preserved, wherein the steps are performed in a processor.

2. The method of claim 1, further comprising
quantizing the phase of the complex-valued measurements.

3. The method of claim 1, further comprising
estimating the angle of multiple signals by measuring an average phase difference between the phases of the complex-valued measurements of the multiple signals.

4. The method of claim 2, further comprising
estimating the angle of two signals by measuring an average phase difference between quantized phase of the complex-valued measurements.

5. The method of claim 1, further comprising:
generating the complex measurement matrix randomly.

6. The method of claim 5, wherein the complex measurement matrix comprises of elements drawn independently from a compex normal distribution.

7. The method of claim 3, further comprising:
storing the phases in a memory;
applying the producing, retaining and storing to a query signal; and
selecting one or more of the multiple signals a smallest angle when compared with the angle of the query signal.

8. The method of claim 7, wherein the memory is part of a server, and further comprising
transmitting the phases from the server to a client; and
returning relevant data related to the one or more selected signals to the client.

9. The method of claim 8, wherein the relevant data are metadata of the signal.

10. The method of claim 8, wherein the relevant data are other signals similar to the signal.

11. The method of claim 8, wherein the database stores a set of embedded signals.

12. The method of claim 8, wherein the searching is performed using a nearest neighbor search.

13. the method of claim 10, further comprising:
using a class of the similar signals to determine a class for the query signal.
